(19) United States
(12) Patent Application Publication
(10) Pub. No.: US 2017/0310337 A1
(43) Pub. Date: Oct. 26, 2017

(54) ELECTRONIC CONTROL UNIT

(71) Applicant: DENSO CORPORATION, Kariya-city (JP)

(72) Inventor: Satoshi ICHIKAWA, Kariya-city (JP)

(21) Appl. No.: 15/410,887

(22) Filed: Jan. 20, 2017

(30) Foreign Application Priority Data
Apr. 21, 2016 (JP) 2016-85203

(51) Int. Cl. H03M 1/76; H03M 1/68; H03M 1/78; H03M 1/48

(52) U.S. Cl. CPC H03M 1/76; H03M 1/78; H03M 1/68; H03M 1/48

(57) ABSTRACT

An electronic control unit includes a pair of D/A conversion circuits, which performs D/A conversion processing of a pair of digital data and outputs a pair of analog signals. Each of the pair of D/A conversion circuits performs the D/A conversion processing by splitting input digital data into more-significant digital data and less-significant digital data. More-significant D/A conversion part performs analog conversion processing in accordance with the more-significant digital data by using an element string circuit, which outputs split voltages by splitting predetermined reference voltages. The more-significant conversion circuits output a maximum value and a minimum value in absolute voltage ranges, which are different from each other, in accordance with the more-significant digital data. Less-significant conversion parts perform analog conversion processing in accordance with less-significant digital data by using the maximum value and the minimum value of the different absolute voltage ranges, which are outputted from the more-significant D/A conversion parts, as reference voltages. The element string circuit is shared by the pair of D/A conversion circuits.

### CROSS REFERENCE TO RELATED APPLICATION

This application is based on Japanese patent application No. 2016-085203 filed on Apr. 21, 2016, the whole contents of which are incorporated herein by reference.

### FIELD

The present disclosure relates to an electronic control unit, which has a digital/analog (D/A) conversion function for performing D/A conversion processing.

### BACKGROUND

An electronic control unit is made capable of performing various controls flexibly with its control part being configured for digital control. For this reason, a D/A converter circuit is preferably used. The D/A converter circuit converts digital data into analog signals. For example, according to JP 4110681, D/A conversion is performed by splitting digital data into a more-significant bit group and a less-significant bit group. According to JP 2004-93289A (US 2004/0045823 A1), a D/A conversion circuit is used in a gas concentration detecting device.

In case of a low-resolution D/A conversion circuit, radio frequency components enter into a sensor and become a noise source. It is preferred to use a high-resolution D/A conversion circuit to minimize such a radio noise. JP 4110681 proposes a high-resolution D/A conversion circuit. However, this proposal needs two D/A conversion circuits in case that a pair of analog signals is applied as a differential voltage to a signal application target by D/A converting a pair of input digital data. Since errors in respective element string circuits are added, a detection target voltage tends to include a large error. Since each of the D/A conversion circuits has an error, D/A conversion accuracy will be lowered.

### SUMMARY

It is therefore an object to provide an electronic control unit having a D/A conversion function, which enables application of a differential voltage with high accuracy and least D/A conversion error.

An electronic control unit, which outputs a pair of analog signals to a signal application target as a differential voltage in correspondence to a pair of input digital data, comprises a pair of D/A conversion circuits for performing D/A conversion processing of converting the pair of input digital data to the pair of analog signals. Each of the D/A conversion circuits performs conversion processing thereof separately by splitting the input digital data into a more-significant digital data and at least one less-significant digital data. The D/A conversion circuit includes a more-significant D/A conversion part and a less-significant D/A conversion part. The more-significant D/A conversion part includes a more-significant element string circuit, which outputs a divided voltage by dividing a predetermined reference voltage and outputs a maximum value and a minimum value of an absolute voltage, which are different each other in correspondence to the more-significant digital data, by performing analog conversion processing in correspondence to the more-significant digital data. The less-significant D/A conversion part performs analog conversion processing by using, as reference voltages, the maximum value and the minimum value of the absolute voltage outputted from the more-significant D/A conversion part. The more-significant element string circuit is shared by the more-significant D/A conversion parts of the pair of D/A conversion circuits.

### BRIEF DESCRIPTION OF THE DRAWINGS

FIG. 1 is an electric circuit diagram showing an electronic control unit according to a first embodiment;

FIG. 2 is a characteristic graph showing a relation between a voltage applied to an air-fuel ratio sensor and a sensor current;

FIG. 3 is a characteristic graph showing in an enlarged manner a part of the relation between the voltage applied to the air-fuel ratio sensor and the sensor current shown in FIG. 2;

FIG. 4 is an electric circuit diagram of a pair of D/A conversion circuits;

FIG. 5 is a plan view schematically showing a layout configuration of an element string circuit;

FIG. 6 is an input-output characteristic graph showing an ideal output and an actual output;

FIG. 7 is an illustration showing in an enlarged manner a part of an actual output characteristic;

FIG. 8 is an input-output characteristic graph showing a comparative example;

FIG. 9 is an explanatory diagram showing a switch-over order of switches of a switch-over circuit in case that digital data are increased gradually;

FIG. 10 is an explanatory diagram showing an input-output characteristic at a point of switch-over of more-significant digital data;

FIG. 11 is an electric circuit diagram of one exemplary pair of D/A conversion circuits according to a second embodiment;

FIG. 12 is an electric circuit diagram of the other exemplary pair of the D/A conversion circuits;

FIG. 13 is a plan view schematically showing a layout configuration of an element string circuit;

FIG. 14 is an electric circuit diagram of a pair of D/A conversion circuits according to a third embodiment; and

FIG. 15 is an electric circuit diagram according to a fourth embodiment.

### EMBODIMENT

An electronic control unit will be described below with reference to several embodiments shown in the drawings. In each of the embodiments described below, structural parts for performing the same or similar operations are designated with the same or similar reference numerals for simplification of description. It is noted that the same or similar structural parts in the embodiments described below are identified with the same reference signs in the ten's place and one's place of the reference sign.

### First Embodiment

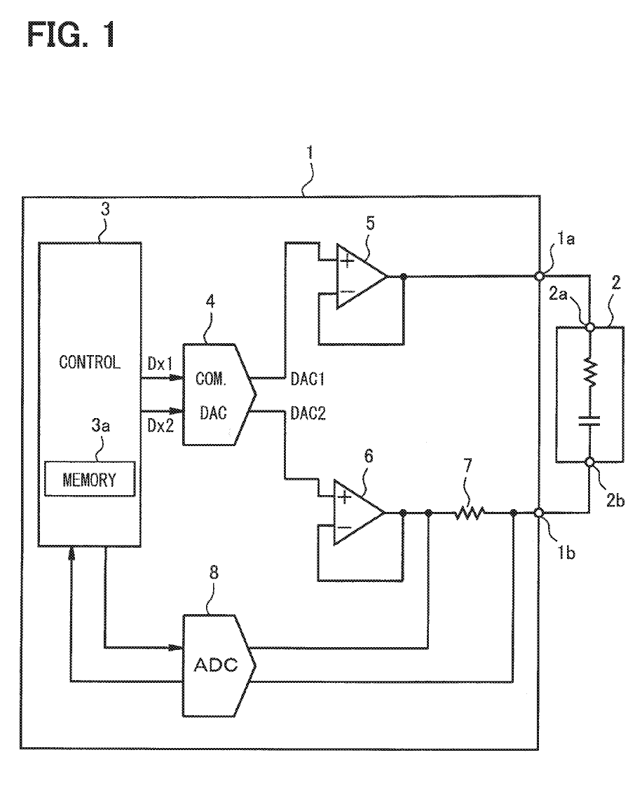

FIG. 1 to FIG. 10 shows a first embodiment. In FIG. 1, electric configuration of a signal processing unit 1 for a gas concentration sensor is shown as an electronic control unit schematically in a block diagram. The signal processing unit 1 shown in FIG. 1 is configured to perform various control processing for an air-fuel ratio sensor 2, which is provided to control an air-fuel ratio of air-fuel mixture supplied to an internal combustion engine (not shown). The air-fuel ratio sensor 2 detects exhaust emission of the internal combustion engine and outputs an analog detection signal, which varies with gas concentration of the exhaust emission. The signal processing unit 1 includes a control part 3, a common D/A converter (COM. DAC) 4, first and second voltage buffers 5, 6 and an A/D converter (ADC) 8.

When the control part 3 outputs a pair of digital data Dx1 and Dx2 to the common D/A converter 4 as first and second command signals, the common D/A converter 4 performs digital-to-analog conversion processing of the pair of digital data Dx1 and Dx2 and applies a pair of conversion-resulting analog signals to the voltage buffers 5 and 6, respectively. The first voltage buffer 5 is formed of a voltage follower circuit of high input impedance and low out impedance. The voltage buffer 5 applies the analog signal of one digital data Dx1, which is produced by the analog conversion processing of the common D/A converter 4, to a high-side terminal 2a of the air-fuel ratio sensor 2 through an output terminal 1a.

The second voltage buffer 6 is also formed of a voltage follower circuit. Its output is connected to a low-potential terminal 2b of the air-fuel ratio sensor 2 through a resistor 7 and an output terminal 1b. The voltage buffer 6 applies the analog signal of the other digital data Dx2, which is produced by the analog conversion processing of the common D/A converter 4, to the low-side terminal 2b of the air-fuel ratio sensor 2 through the resistor 7. Thus a differential voltage between the analog signals applied to the sensor terminals 2a and 2b is applied as a bias voltage to the air-fuel ratio sensor 2. The control part 3 is formed of a digital signal processor (DSP), for example, and operates based on programs stored in a built-in memory part 3a. The memory part 3a is a volatile memory or a non-volatile memory such as a flash memory, for example.

The resistor 7 is provided in a current supply path for the air-fuel ratio sensor 2 to detect a sensor current, which flows in the air-fuel ratio sensor 2. The A/D converter 8 receives terminal voltages of the resistor 7, performs analog-to-digital conversion processing and outputs a digital conversion result to the control part 3. The control part 3 outputs the pair of digital data Dx1 and Dx2 to the common D/A converter 4 as command signals based on the digital conversion results. Thus a supply voltage to the air-fuel ratio sensor 2 is regulated by feedback control.

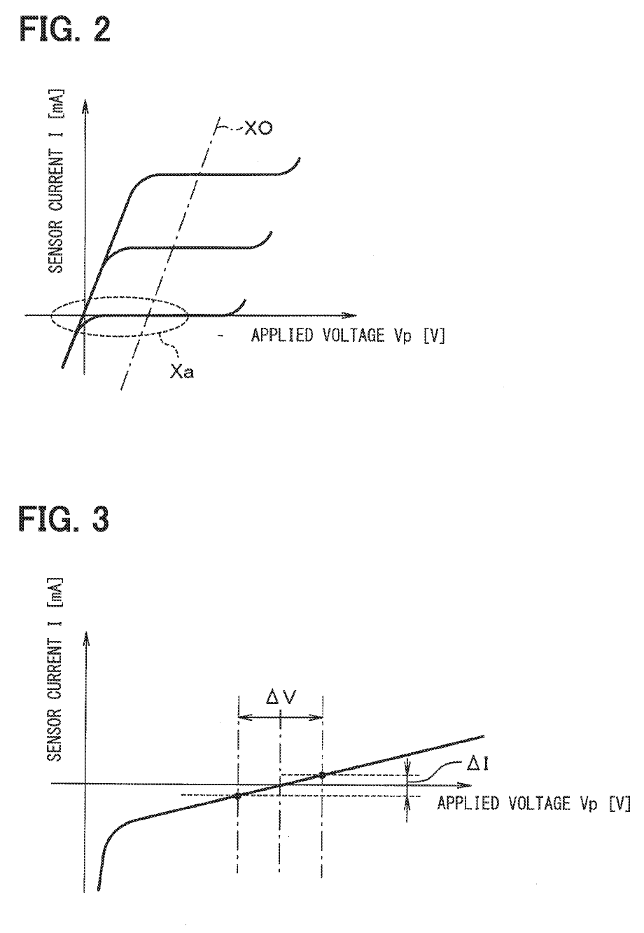

A voltage-current (V-I) characteristic of the air-fuel ratio sensor 2 is shown in FIG. 2. A part of the characteristic shown in FIG. 2, which is indicated with Xa, is shown in FIG. 3 in an enlarged manner. In FIG. 2 and FIG. 3, a slightly inclined characteristic relative to an axis of abscissa indicating the applied voltage Vp indicates a limit current range, which defines an element current I flowing in a sensor element of the air-fuel ratio sensor 2. Increase and decrease in the element current correspond to increase and decrease of the air-fuel ratio (lean and rich), respectively. For example, the element current increases and decreases as the air-fuel mixture becomes lean and rich, respectively.

A characteristic line XO indicated by a one-dot chain line in FIG. 2 indicates an applied voltage line, based on which the applied voltage for the air-fuel ratio sensor 2 is to be determined. As shown in FIG. 3, when the applied voltage for the air-fuel ratio sensor 2 varies by an amount ΔV, the sensor current I flowing in the air-fuel ratio sensor 2 also varies by an amount ΔI. For this reason, the air-fuel ratio sensor 2 need be controlled with high accuracy.

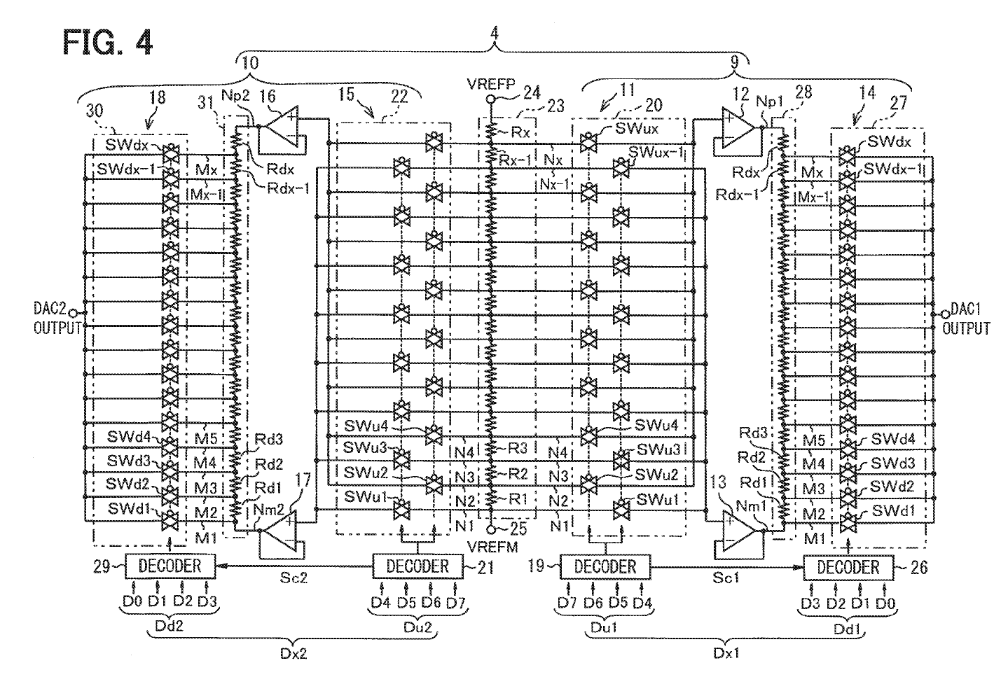

As shown in FIG. 4, the common D/A converter 4 is formed of a pair of (first and second) D/A conversion circuits 9 and 10. The first D/A conversion circuit 9 includes a first more-significant D/A conversion part 11, buffer circuits 12, 13 and a first less-significant D/A conversion part 14. The second D/A conversion circuit 10 includes a second more-significant D/A conversion part 15, buffer circuits 16, 17 and a second less-significant D/A conversion part 18. In the first embodiment, one digital data applied from the control part 3 to the D/A conversion circuit 9 as first digital data and the other digital data applied from the control part 3 to the D/A conversion circuit 10 as second digital data are assumed to be Dx1 and Dx2, respectively.

The more-significant digital data applied to the more-significant D/A conversion parts 11 and 15 are assumed to be Du1 and Du2 of “n1” bits. The less-significant digital data applied to the less-significant D/A conversion parts 14 and 18 are assumed to be Dd1 and Dd2 of “n2” bits. In the first embodiment, although the digital data is split into two parts of a more-significant part and a less-significant part, it may be split into three or more parts. It is noted that, the more-significant data and circuit elements for the more-significant data are identified by using a sign “u” indicating an upside (higher bit side) and the less-significant data an circuit elements for the less-significant data are identified by using a sign “d” indicating a downside (lower bit side).

The more-significant D/A conversion part 11 includes a first more-significant decoder 19 and a second more-significant switch-over circuit 20 for the first more-significant digital data Du1. The second more-significant D/A conversion part 15 includes a second more-significant decoder 21 and a second more-significant switch-over circuit 22 for the second more-significant digital data Du2. The pair of more-significant A/D conversion parts 11 and 15 is configured to share an element string circuit 23, which is provided as a common element string circuit or a more-significant element string circuit for the more-significant A/D conversion parts 11 and 15. The pair of more-significant A/D conversion parts 11 and 15 is configured in a resistor string form, that is, a series-connected resistor circuit.

The element string circuit 23 is formed of a voltage-dividing resistor circuit, which divides reference voltages VREFP and VREFM applied to reference voltage terminals 24 and 25. The element string circuit 23 includes, for example “2n1” units of voltage-dividing resistors R1 to Rx connected between the reference voltage terminals 24 and 25. Each of the voltage-dividing resistors R1 to Rx is set to have the same resistance value. In this arrangement, the divided voltage in the element string circuit 23 is defined as follows.

V(Na)=VREFM+(a−1)×(VREFP−VREM)/2n1 (1)

Here, “a” is between 1 and 2n1 (1≦a≦2n1) and a node Na between resistors is an “a” th terminal node form the bottom of the voltage dividing circuit, which forms the element string circuit 23 (refer to nodes N1 to Nx shown in FIG. 4).

The first and second D/A conversion circuits 9 and 10 have the symmetrical configuration with each other except for the element string circuit 23, which is shared. For this reason, detailed circuit connection and circuit operation of the D/A conversion circuit, which are the same, will be described with respect to only the first D/A conversion circuit 9 thereby simplifying the description of the second D/A conversion circuit 10.

The more-significant decoders 19 and 21 generate selection signals in correspondence to the more-significant digital data Du1 and Du2 applied thereto and output the selection signals to the more-significant switching circuits 20 and 22, respectively. The first and second more-significant decoders 19 and 21 are configured to output to the first and second less-significant decoders 26 and 29 first and second control signals, which indicate a state that the more-significant bits become an odd number and even number (that is, the least-significant bit data D4 of the more-significant digital data Du1 and Du2 become 0 or 1), respectively.

The more-significant switch-over circuit 20 is configured to include switches SWu1 to SWux, which switch-over signals of nodes N1 to Nx to be outputted. The more-significant switch-over circuit 20 receives the selection signal of the more-significant decoder 19 and outputs a divided voltage of the voltage-dividing resistors R1 to Rx of the element string circuit 23. The more-significant switch-over circuit 20 is configured to output voltages, which are different from each other in an absolute voltage range when the more-significant digital data Du1 are different, in accordance with the more-significant digital data. Similarly, the more-significant switch-over circuit 22 is configured to output voltages, which are different from each other in an absolute voltage range, when the more-significant digital data Du2 are different, in accordance with the more-significant digital data Du2. Detailed configuration of the more-significant switch-over circuit 22 will not be described.

The more-significant switch-over circuit 20 simultaneously turns on a pair of switches (for example, SWu1-SWu2, SWu2-SWu3, and the like), which are adjacent in FIG. 4, in correspondence to the selection signal of the more-significant decoder 19. The more-significant switch-over circuit 20 turns off other switches. That is, the more-significant switch-over circuit 20 selectively outputs the voltages V(Na+1) and V(Na) of the element string circuit 23 by switching. By thus selecting the pair of voltages V(Na) and V(Na+1) in correspondence to the more-significant digital data Du1, the more-significant switch-over circuit 20 outputs reference voltages, which are in absolute voltage ranges having the pair of voltages V(Na) and V(Na+1) as local values (maximum value and minimum value).

When the more-significant digital data Du1 increases from 0 to 2n1−1 in succession, the more-significant switch-over circuit 20 switches over to sequentially output from the terminal voltage of the least-significant voltage-dividing resistor R1, terminal voltage of the next least-significant resistor R2 and finally to terminal voltage of the most-significant voltage dividing resistor Rx−1 in correspondence to the selection signal of the more-significant decoder 19.

When the more-significant digital data Du1 decreases from 2n1−1 to 0 in succession, the more-significant switch-over circuit 20 switches over to sequentially output from the terminal voltage of the voltage-dividing resistor Rx−1, which is one less the most-significant voltage-dividing resistor Rx, to finally terminal voltage of the least-significant voltage dividing resistor R1 in correspondence to the selection signal of the more-significant decoder 19.

For example, when the more-significant digital data Du1 is a maximum value at 4-bit data value 1111, the more-significant decoder 19 outputs the selection signal to output the terminal voltage of the most-significant side resistor Rx−1 in FIG. 4. The more-significant switch-over circuit 20 outputs the terminal voltage of the resistor Rx−1, which is at the most-significant side, of the element string circuit 23 in response to the selection signal. Further, for example, when the more-significant digital data Du1 is a minimum value at 4-bit data value 0000, the more-significant decoder 19 outputs the selection signal to output the terminal voltage of the least-significant side resistor R1 in FIG. 4. The more-significant switch-over circuit 20 outputs the terminal voltage of the resistor R1, which is at the least-significant side, of the element string circuit 23 in response to the selection signal.

The buffer circuit 12 receives the voltage outputted from the more-significant switch-over circuit 20. The buffer circuit 12 is connected to receive one of outputs of the nodes N1, N3 and so on in response to turn-on of the odd-numbered switches SWu1, SWu3 and so on.

The buffer circuit 13 also receives the voltage outputted from the more-significant switch-over circuit 20. The buffer circuit 13 is connected to receive one of outputs of the switches SWu1, SWu3 and so on, which are connected to the odd-numbered nodes N1, N3 and so on. Each of the first and second buffer circuits 12 and 13 is configured as a voltage-follower circuit, for example, which has a high input impedance and a low output impedance. Each output of the first and second buffer circuits 12 and 13 is applied to the less-significant D/A conversion part 14 as a reference voltage of the less-significant D/A conversion part 14.

The output of the buffer circuit 12 is applied to a most-significant node Np1 of an element string circuit 28, which is provided as a less-significant element string circuit as opposed to the more-significant element string circuit 23. The output of the buffer circuit 13 is applied to a least-significant node Nm1 of the element string circuit 28 of the less-significant D/A conversion part 14. The output of the buffer circuit 16 is applied to a most-significant node Np2 of the element string circuit 31, which is provided as a less-significant element string circuit similarly to the element string circuit 28. The output of the buffer circuit 17 is applied to a least-significant node Nm2 of the element string circuit 31 of the less-significant D/A conversion part 18.

The less-significant D/A conversion part 14 includes a less-significant decoder 26, a less-significant switch-over circuit 27 and a less-significant second element string circuit 28. The less-significant D/A conversion part 18 includes a less-significant decoder 29, less-significant switch-over circuit 30 and a less-significant second element string circuit 31. The less-significant D/A conversion part 18 has the same configuration as the less-significant D/A conversion part 14. Hence, circuit connection and operation of the less-significant D/A conversion part 18 will not be described. A pair of less-significant D/A conversion parts 14 and 18 also has the resistor string configurations.

The element string circuit 28 is formed of a voltage dividing resistor circuit, which divides voltages applied to nodes Np1 and Nm1 as reference voltages, respectively. The more-significant switch-over circuit 20 includes, for example, 2×n2 units of voltage-dividing resistors Rd1 to Rdx connected between the pair of nodes Np1 and Nm1. Each of the voltage-dividing resistors Rd1 to Rdx is set to have the same resistance value. The element string circuit 28 outputs voltages divided by the voltage dividing resistors Rd1 to Rdx. Here, “b” is between 1 and 2n2 (1:5≦b:≦2n2) and a node Mb is a “b” th terminal node from the bottom of the element string circuit 28. The voltage V(Mb) is different between two cases, that is, “a” is an odd number and “a” is an even number, based on on/off states of the switches SWu1 to SWux of the more-significant switch-over circuit 20 in consideration of the circuit connection between the more-significant D/A conversion part 11 and the voltage buffer circuits 12 and 13. When “a” is the odd number, the voltage V(Mb) is defined as follows.

V(Mb)=V(Na)+(b−1)×{V(Na+1)−V(Na)}/2n2 (2-1)

When “a” is the even number, the voltage V(Mb) is defined as follows.

V(Mb)V(Na)(2n2−b(Na)+(2n2−b)×{V(Na+1)−V(Na)}/2n2 (2-2)

The voltages V(Na+1) and V(Na) indicate the output voltages of the more-significant D/A conversion part 11, respectively. The less-significant decoder 26 generates a selection signal in correspondence to the less-significant digital data Dd1 and outputs it to the less-significant switch-over circuit 27. The less-significant switch-over circuit 27 includes switches SWd1 to SWdx, which switches over outputting of signals of the nodes M1 to Mx.

The less-significant decoder 26 changes the selection signals, which are to be outputted to the less-significant switch-over circuit 27, in correspondence to the control signal Sc1 applied from the more-significant decoder 19. When the least-significant bit data D4 of the more-significant digital data Du1 satisfies the even number condition and the less-significant digital data Dd1 sequentially increases, the less-significant decoder 26 outputs the selection signals to turn on the switches SWd1 to SWdx of the less-significant switch-over circuit 27, that is, to turn on from a bottom side to a top side in FIG. 4. When the least-significant bit data D4 of the more-significant digital data Du1 satisfies the odd number condition and the less-significant digital data Dd1 sequentially increases, the less-significant decoder 26 outputs the selection signals to turn on the switches SWdx to SWd1 of the less-significant switch-over circuit 27, that is, to turn on from the side to the bottom side in FIG. 4.

The less-significant switch-over circuit 27 receives the selection signals of the less-significant decoder 26 and outputs the divided voltages of the voltage dividing resistors Rd1 to Rdx of the element string circuit 28. The less-significant switch-over circuit 27 turns on one of the switches (for example, SWd1) in correspondence to the selection signal of the less-significant decoder 26 and turns off other switches. That is, the less-significant switch-over circuit 27 outputs the divided voltage V by switching.

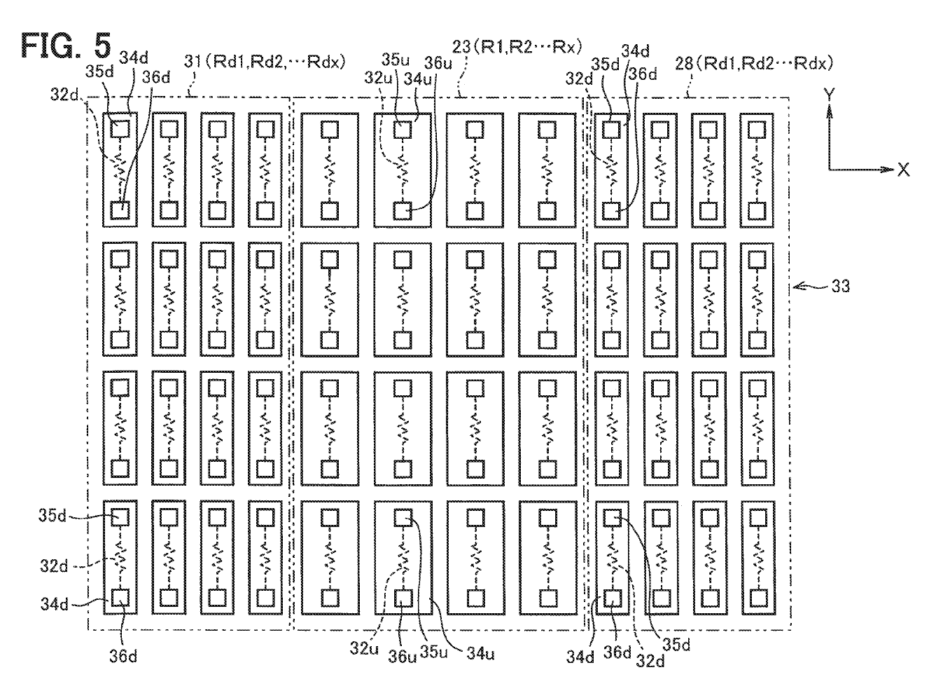

Planar arrangement of the more-significant element string circuit 23 and the less-significant element string circuits 28 and 31 will be described with reference to FIG. 5. FIG. 5 shows a planar layout on a surface of a substrate forming a semiconductor device 33, for example. In this figure, one of directions of a substrate surface is assumed to be an X direction and the other of the direction, which crosses perpendicularly to the X direction on the substrate surface, is assumed to be a Y direction. FIG. 5 shows a planar layout of resistors assuming that n1 and n2 are 4 bits.

On the planar layout, areas of the less-significant element string circuits 28 and 31 are provided on both sides (right and left in the figure) of an area of the element string circuit 23 to be spaced apart in the X direction. The voltage-dividing resistors R1 to Rx of the element string circuit 23 are arranged on lattice points of n1×n1 lattice in the area of the element string circuit 23. The voltage-dividing resistors R1 to Rx of the element string circuit 28 and the element string circuit 31 are arranged on lattice points of n2×n2 lattice in the areas of the element string circuit 28 and the element string circuit 28, respectively.

In the semiconductor device 33; the element string circuit 23 includes resistor elements 32u, which form the voltage-dividing resistors R1 to Rx. The resistor element 32 is formed by using a wiring layer 34u of a poly-silicone semiconductor layer or a metallic layer.

Each of the element string circuit 28 and the element string circuit 31 also includes resistor elements 32d, which form the voltage-dividing resistors R1 to Rx. The resistor element 32 is formed by using a wiring layer 34d of a poly-silicone semiconductor layer or a metallic layer in the semiconductor device 33.

The wiring layers 34u and 34d are formed to be the same layer. The resistor elements 32u and 32d are provided to extend in the Y direction. Contacts 35u and 36u are provided at both ends of the resistor element 32u in the Y direction. Thus the contacts 35u and 36u enable acquisition of the divided voltages. Contacts 35d and 36d are provided at both ends of the resistor element 32d in the Y direction. Thus the contacts 35d and 36d enable acquisition of the divided voltages.

The wiring layers 34u, which form the voltage-dividing resistors R1 to Rx, have the same widths in the X direction and the same widths in the Y direction. The wiring layers 34d, which form the voltage-dividing resistors Rd1 to Rdx, have the same widths in the X direction and the same widths in Y direction. The voltage-dividing resistors R1 to Rx of the more-significant side and the less-significant side have the same heights in a depth direction (vertical direction to the drawing sheet, that is, perpendicular to both X and Y directions).

Relative relation between the widths of the voltage-dividing resistors R1 to Rx and the voltage-dividing resistors Rd2 to Rdx is defined as follows. Each width of the voltage-dividing resistors R1 to Rx of the more-significant side in the X direction is structured to be wider than that of the voltage-dividing resistors Rd1 to Rdx of the less-significant side. As a result, each cross-sectional area of the voltage-dividing resistors R1 to Rx in the X-Z direction is structured to be wider than that of the voltage dividing resistors Rd1 to Rdx of the less-significant side.

Each cross-sectional area of the voltage-dividing resistors R1 to Rx in the X-Z direction is thus structured to be wider than that of the voltage dividing resistors Rd1 to Rdx of the less-significant side for the reason that a resistance error of the voltage-dividing resistor R1 to Rx of the more-significant side is decreased as little as possible. That is, since a D/A conversion error arising based on the more-significant digital data Du1 is amplified in accordance with the resistance error of the voltage-dividing resistors R1 to Rx of the more-significant side, it is preferred to decrease the error of the resistance for decreasing the D/A conversion error.

In consideration of design rule for manufacturing the wiring layers 34u and 34d, a manufacturing error in a manufacturing process is determined to be a predetermined width. For this reason, a rate of the manufacturing error is decreased by setting the width of the wiring layer 34u in the X direction to be larger than that of the wiring layer 34d in the X direction. The resistance values of the voltage-dividing resistors R1 to Rx are made to be more accurate than the resistance values of the voltage-dividing resistors Rd1 to Rdx.

Further, with this structural setting, the resistance values of the voltage-dividing resistors R1 to Rx of the more-significant side are made to be lower than the resistance values of the voltage-dividing resistors Rd1 to Rdx of the more-significant side. As a result, a time constant determined in combination with input capacitances of the voltage buffer circuits 12 and 13 is decreased and the D/A conversion signal output corresponding to the more-significant digital data Du1 is stabilized quickly.

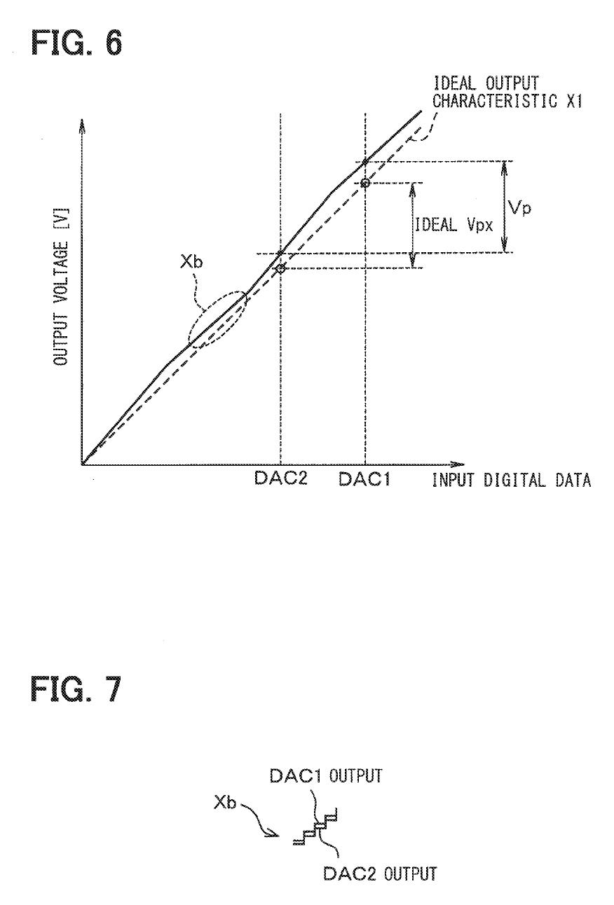

An A/D conversion output characteristic which corresponds to a pair of input digital data Dx1 and Dx2 of n1+n2 bits (more-significant Du1 and less-significant Dd1, more-significant Du2 and less-significant Dd2), and a voltage applied to the air-fuel ratio sensor 2 will be described with reference to FIG. 6 and FIG. 7.

In case that the voltage-dividing resistors R1 to Rx of the element string circuit 23 generate an error from an ideal standard value indicated by a dotted line in FIG. 6 for example, the pair of D/A conversion circuits 9 and 10 output voltages, which deviate from the ideal output characteristic X1 because of the error of the voltage-dividing resistors R1 to Rx, as indicted by a solid line in FIG. 6.

In the first embodiment, however, the element string circuit 23 of the more-significant D/A conversion parts 11 and 15 is shared by the pair of D/A conversion circuits 9 and 10. For this reason, as shown in FIG. 6, outputs of the pair of D/A conversion circuits 9 and 10 become slightly higher or lower than the ideal output characteristic X1 because of conversion errors of the pair of more-significant digital data Du1 and Du2. However, influences of errors of the voltage-dividing resistors R1 to Rx are in the same direction, for example, high voltage direction in FIG. 6. For this reason, even in case that the less-significant D/A conversion part 14 and 18 of the following stage cause conversion errors in the D/A conversion of the less-significant digital data Dd1 and Dd2, influence of error in the conversion of the less-significant digital data Dd1 and Dd2 is small as shown in FIG. 7, which shows in enlargement a characteristic indicated as an area Xb in FIG. 6.

Thus, as shown in FIG. 6, by applying from the signal processing unit 1 the analog signal outputs DAC1 and DAC2 to the sensor terminals 2a and 2b of the air-fuel ratio sensor 2 as the differential voltage through the voltage buffers 5 and 6, the applied voltage Vp generally becomes equal to the ideal applied voltage Vpx.

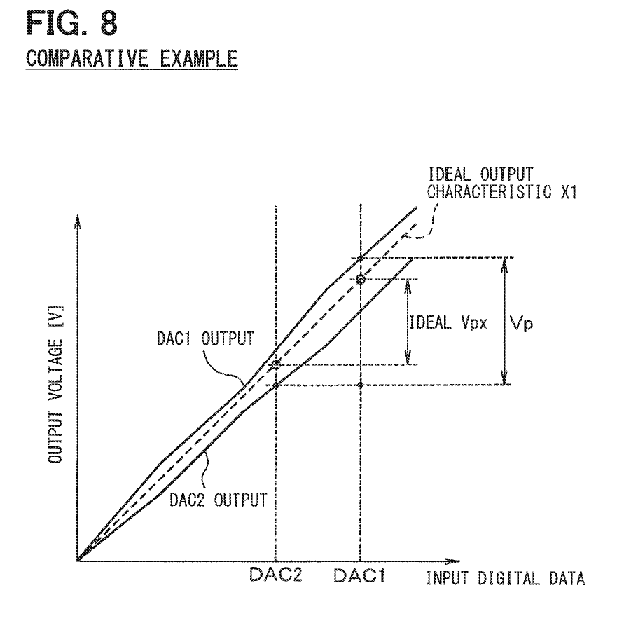

FIG. 8 shows, as one comparative example, an output characteristic of an analog signal, which is produced in case that the element string circuit 23 is not shared by the pair of D/A conversion circuits 9 and 10, and a voltage applied to the air-fuel ratio sensor 2. In case that the element string circuit 23 is not shared by the pair of D/A conversion circuits 9 and 10, influence of errors of the more-significant voltage-dividing resistors R1 to Rx appears in both of the pair of D/A conversion circuits 9 and 10 separately. FIG. 8 shows a worst case, in which the analog signal output DAC1 of the D/A conversion circuit 9 is higher than the ideal output characteristic X1 and the analog signal output DAC2 of the D/A conversion circuit 10 is lower than the ideal output characteristic X2. For this reason, in case that the outputs of the pair of D/A conversion circuits 9 and 10 are applied to the sensor terminals 2a and 2b of the air-fuel ratio sensor 2 as the differential voltage, the applied voltage Vp deviates largely from the ideal applied voltage Vpx as shown in FIG. 8.

That is, according to the first embodiment, by equalizing errors of the more-significant side voltage-dividing resistors R1 to Rx between the D/A conversion circuits 9 and 10, the conversion error is decreased largely. Further, by applying the differential voltage to the air-fuel ratio sensor 2, the error of the differential voltage corresponding to the more-significant side voltage dividing resistors R1 to Rx is canceled out. As a result, conversion error is minimized remarkably.

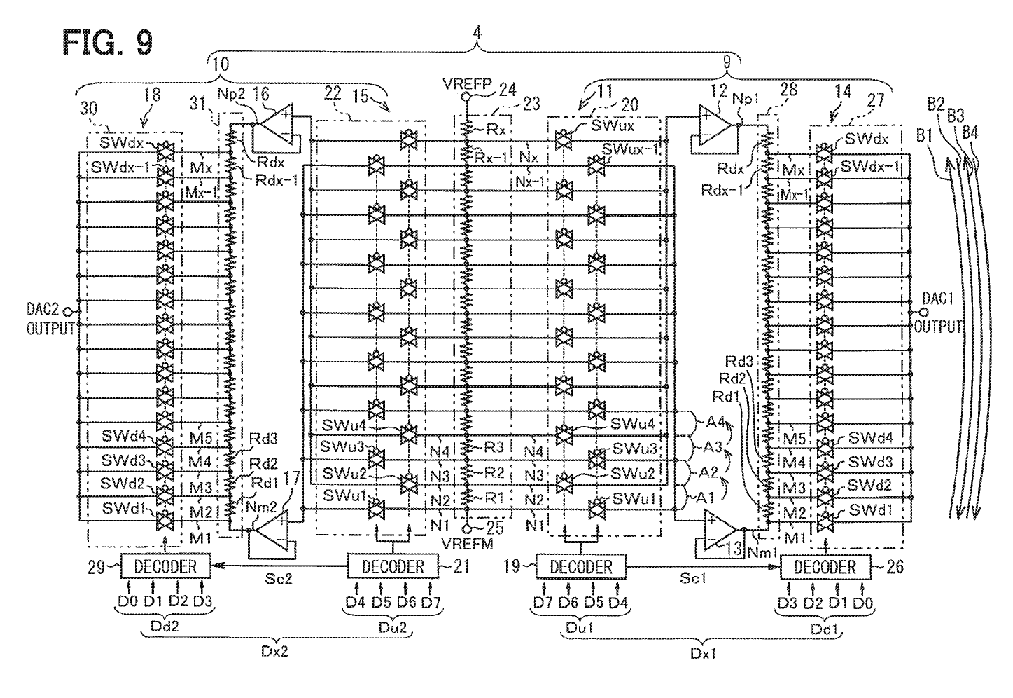

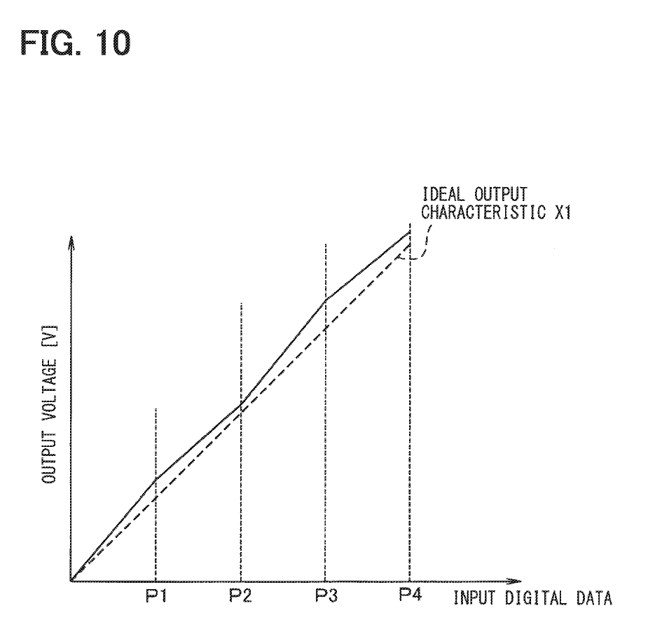

Changes in switch-over operations of the more-significant switch-over circuit 20 and the less-significant switch-over circuit 27 performed in response to a control signal Sc1 when the digital data Dx1 is changed to increase continuously will be described in detail with reference to FIG. 9 and FIG. 10.

For simplification of description, the D/A conversion operation of the D/A conversion circuit 9 will be described assuming that the digital data Dx1 is split into digital data Du1 and Dd1, which are more-significant n1 bits (4 bits) and less-significant n2 bits (4 bits) and inputted to the more-significant decoder 19 and the less-significant decoder 26, respectively. Here, the number of bits n1 and n2 of each input digital data Dx1 is not limited to four.

For example, the digital data Dx1 is 0b00000000, the more-significant decoder 19 outputs the on-selection signal to the switches SWu1 and SWu2 of the more-significant switch-over circuit 20 to turn on the switches SWu1 and SWu2 (refer to a pair indicated as A1 in FIG. 9) and turns off other switches. Thus, a voltage of VREFM+ 1/16×(VREFP−VREFM) is applied to the buffer circuit 12 and a voltage of VREFM is applied to the buffer circuit 13.

The more-significant decoder 19 outputs a control signal, which indicates that the more-significant digital data Du1 is an odd number, to the less-significant decoder 26. The less-significant decoder 26 outputs the on-selection signal to the switch SWd1 of the less-significant switching circuit 27 to turn on the switch SWd1. At this time, the output voltage applied to the node Np1 of the buffer circuit 12 is higher than that applied to the node Nm1 of the buffer circuit 13. The output voltage of the buffer circuit 12 is used as the more-significant reference voltage of the less-significant D/A conversion part 14. The output voltage of the buffer circuit 13 is used as the less-significant reference voltage of the less-significant D/A conversion part 14. In this case, the voltage V(M1)=V(N)=VREFM, which is defined by the equation (2-1) assuming that “a” is 1 and “b” is 1, is produced as the analog signal output DAC1 through the switch SWd1.

For example, when the digital data Dx1 is incremented to 0b00000001, the output of the more-significant decoder 19 does not change. The less-significant decoder 26 outputs the on-selection signal to the switch SWd2 of the less-significant switch-over circuit 27 to turn on the switch SWd2 and turns off the other switches. In this case, the voltage V(M2) is defined as V(M2)=VREFM+(1/16)×(VREFP−VREFM)/16 by the equation (2-1) assuming that “a” is 1 and “b” is 2. This voltage V(M2) is produced as the analog signal output DAC1.

When the digital data Dx1 is incremented from 0b00000000 to 0b00001111 sequentially, the less-significant decoder 26 turns on the switches SWd1 to SWdx of the less-significant switch-over circuit 27 in sequence and turns off the other switches, thereby increasing the output voltage of the element string circuit 28 sequentially. The order of switching is indicated by an arrow B1 in FIG. 9. In this case, the output voltage of the element string circuit 28 is indicated mathematically by using the equation (2-1). With “b” in the equation (2-1) increasing from 1 to 16 sequentially, the voltages V(M1) to V(M16) defined by the equation (2-1) is outputted as the analog signal outputs DAC1.

When the digital data Dx1 is incremented to 0b00010000=16, the more-significant decoder 19 outputs the on-selection signals to the switches SWu2 and SWu3 of the more-significant switch-over circuit 20 to turn on the switches SWu2 and SWu3 (refer to the pair indicated by A2 in FIG. 9) and turns off the other switches. “0b” indicates a binary number.

At this time, the more-significant switch-over circuit 20 maintains the voltage V(N2), which was previously selected, to be applied to the buffer circuit 12 and switches over the voltage V(N1), which was selected previously, to the voltage V(N3) to be applied to the buffer circuit 12. Thus the voltage defined as V(N2)=VREFM+1/16×(VREFP−VREFM) is applied to the buffer circuit 12. With this voltage V(N2) being maintained to be applied as one reference voltage of the less-significant D/A conversion part 14, the voltage defined as V(N3)=VREFM+1/16×(VREFP−VREFM) is applied to the buffer circuit 13. This voltage V(N3) is applied as the other reference voltage of the less-significant D/A conversion part 14.

With the voltage relation V(N3)>V(N2), the output voltage V(N4) of the buffer circuit 12 is used as the more-significant reference voltage of the less-significant D/A conversion part and the output voltage V(N3) of the voltage buffer circuit 13 is used as the less-significant reference voltage of the less-significant D/A conversion part 14.

When the digital data Dx1 reaches 0b00010000=16, the more-significant digital data Du1 becomes an odd number. For this reason, in response to the control signal outputted from the more-significant decoder 19 to the less-significant decoder 26, the less-significant decoder 26 switches over a switch control direction to turn on the switches SWdx to SWd1 of the less-significant switch-over circuit 27 sequentially, that is, from top side to bottom side in FIG. 9 as indicated by an arrow B2.

When the digital data Dx1 is incremented from 0b00010000 to 0b00011111 sequentially, the less-significant decoder 26 turns on the switches SWdx to SWd of the less-significant switch-over circuit 27 in sequence and turns off the other switches, thereby increasing the output of the divided voltage sequentially. In this case, the output voltage is indicated mathematically by using the equation (2-2) with the more-significant digital data Du1 is the odd number. When the digital data Dx1 is 0b00010000=16, the voltage V(M16)=V(N2)+1/16×(VREFP−VREFM) is outputted as the analog signal output DAC1 assuming that “a” is 2 and “b” is 16.

When the digital data Dx1 is incremented from 0b00010000 to 0b0001111 sequentially, “b” in the equation (2-2) is decreased to 1 sequentially and the voltages V(M16) to V(M1) indicated by the equation (2-2) are produced as the analog signal outputs DAC1. That is, when the digital data Dx1 is incremented, the output gradually increases from V(M16) to V(M1).

When the digital data Dx1 is incremented to 0b00100000, the most-significant bit data D4 of the more-significant digital data Du1 becomes the even number again. The more-significant decoder 19 outputs the on-selection signals to the switches SWu3 and SWu4 of the more-significant switch-over circuit 20 to turn on the switches SWu3 and SWu4 (refer to a pair indicated as A3 in FIG. 9) and turn off the other switches.

The more-significant switching circuits 20 and 22 maintain the voltage V(N3), which was previously selected, to be applied to the buffer circuit 13 and switches over the voltage V(N2), which was selected previously, to the voltage V(N4) to be applied to the buffer circuit 12. Thus the voltage defined as V(N4)=VREFM+3/16×(VREFP−VREFM) is applied to the buffer circuit 12. With this voltage V(N4) being maintained to be applied as one reference voltage of the less-significant D/A conversion part 14, the voltage defined as V(N3)=VREFM+2/16×(VREFP−VREFM) is applied to the buffer circuit 13. This voltage V(N3) is applied as the other reference voltage of the less-significant D/A conversion part 14. With the voltage V(N4)>V(N3), the output voltage V(N4) of the buffer circuit 12 is used as the more-significant reference voltage of the less-significant D/A conversion part 14 and the output voltage V(N3) of the voltage buffer circuit 13 is used as the less-significant reference voltage of the less-significant D/A conversion part 14.

When the digital data Dx1 reaches 0b00010000=16, the more-significant digital data Du1 becomes the odd number. For this reason, in response to the control signal outputted from the more-significant decoder 19 to the less-significant decoder 26, the less-significant decoder 26 switches over a switch control direction to turn on the switches SWd1 to SWdx of the less-significant switch-over circuit 27 sequentially, that is, from the bottom side to the top side in FIG. 9 as indicated by an arrow B3.

Accordingly, when the digital data Dx1 is incremented from 0b00010000 to 0b00011111 sequentially, the less-significant decoder 26 turns on the switches SWd1 to SWdx of the less-significant switch-over circuit 27 in sequence and turns off the other switches, thereby increasing the output of the divided voltage sequentially. In this case, the output voltage is indicated mathematically by using the equation (2-1) with the more-significant digital data Du1 is the even number. When the digital data Dx1 is 0b00100000=36, the voltage defined as V(M1)=V(N3)=VREFM+2/16×(VREFP−VREFM) by the equation (2-1) is outputted as the analog signal output DAC1 through the buffer circuit 13 and the switch SWd1 assuming that “a” is 3 and “b” is 1.

The operation described above is repeated as the digital data Dx1 is incremented sequentially. That is, as the digital data Dx1 is increased sequentially, the more-significant switch-over circuit 20 of the more-significant D/A conversion part 11 sequentially turns on the paired switches SWu1 to SWux in an order from A1 to A4 and so on, respectively. The less-significant switch-over circuit 27 of the less-significant D/A conversion part 14 sequentially turns on the switches SWd1 to SWdx in an order from B1 to 84 and so on, respectively. In case that the digital data Dx1 decreases sequentially, the operation is the opposite to the operation of above-described case, in which the digital data Dx1 increases. Its operation will not be described.

FIG. 10 shows data points P1 and P3, at which the more-significant digital data Du1 switches over from the even number to the odd number, and points P2 and P4, at which the more-significant digital data Du1 switches over from the odd number to the even number. As shown in FIG. 10, the output characteristic, that is, a change rate of the output voltage relative to the input digital data varies in correspondence to switch-over of the more-significant digital data Du1. This is because the offsets of the voltage buffer circuits 12 and 13 often influence differently.

For example, at the data points P1 and P3, at which the more-significant digital data Du1 changes from the even number to the odd number, the input to the buffer circuit 13 switches over and the input to the buffer circuit 12 does not switch over between the pair of buffer circuits 12 and 13. The input switch-over is opposite at the data points P2 and P4, at which the more-significant digital data changes from the odd number to the even number. For this reason, since the more-significant switch-over circuit 20 and the less-significant switch-over circuit 27 switches over the switches as described above, the change rate of the output voltage relative to the input digital data at the data points P1 to P4 is decreased. Thus the influence of offsets of the voltage buffer circuits 12 and 13 is decreased and hence the input-output linearity at the switch-over points P1 to P4 of the input digital data Dx1 is improved.

As described above, since the element string circuit 23 is shared by the pair of D/A conversion parts 11 and 15 in the first embodiment, the D/A conversion errors of the more-significant digital data Du1 and Du2 arising from the error of the element string circuit 23 are made to match between the pair of more-significant D/A conversion parts 11 and 15 thus decreasing the D/A conversion error arising from the more-significant digital data Du1 and Du2. Accordingly, in case that the less-significant D/A conversion parts 14 and 18 perform the analog conversion processing in correspondence to the less-significant digital data Dd1 and Dd2 by using as the reference voltages the maximum value and the minimum value in the range of the absolute voltages, which the more-significant D/A conversion parts 11 and 15 output, the D/A conversion error does not become large even when the conversion error is present in the less-significant digital data Dd1 and Dd2. It is thus possible to apply the differential voltage of high accuracy to the sensor terminals 2a and 2b of the air-fuel ratio sensor 2. Further, it possible to decrease a space for circuit arrangement because the element string circuit 23 is shared by the D/A conversion circuits 9 and 10.

When the more-significant digital data Du1 is incremented, the more-significant switch-over circuits 20 and 22 input one voltage, for example V(N2), which was selected previously, to the buffer circuit 12 as one reference voltage, and switches over the other voltage from V(N1) to V(N3) to be inputted to the second buffer circuit 13 as the other reference voltage.

When the more-significant digital data Du1 is incremented further, the more-significant switch-over circuits 20 and 22 input the other voltage, for example V(N3), which was selected previously, to the buffer circuit 13 as the other reference voltage, and switches over the voltage, which was selected previously, from V(N2) to V(N4) to be inputted to the first buffer circuit 12 as one reference voltage. As a result, it is possible to decrease the influence of the offsets of the voltage buffer circuits 12 and 13 and improve the input-output characteristic of the input digital data Dx1 at the switch-over points P1 to P4.

The resistors R1 to Rx of the element string circuit 23 of the more-significant D/A conversion part 11 have higher accuracy than the resistors Rd1 to Rdx of the element string circuit 28 of the less-significant D/A conversion part 14. It is therefore possible to reduce the conversion error based on the more-significant digital data Du1 and Du2.

The element string circuit 23 is formed of the semiconductor device 33, which uses the voltage-dividing resistor circuit of the voltage-dividing resistors R1 to Rx. The more-significant D/A conversion parts 11 and 15 are configured such that a cross-sectional area, through which the current passes the voltage-dividing resistors R1 to Rx of the element string circuit 23, is larger than that of the element string circuit 28 of the less-significant D/A conversion parts 14 and 18. It is therefore possible to decrease the resistance value of the voltage-dividing resistors R1 to Rx of the more-significant element string circuit 23 and increase the response speed.

### Second Embodiment

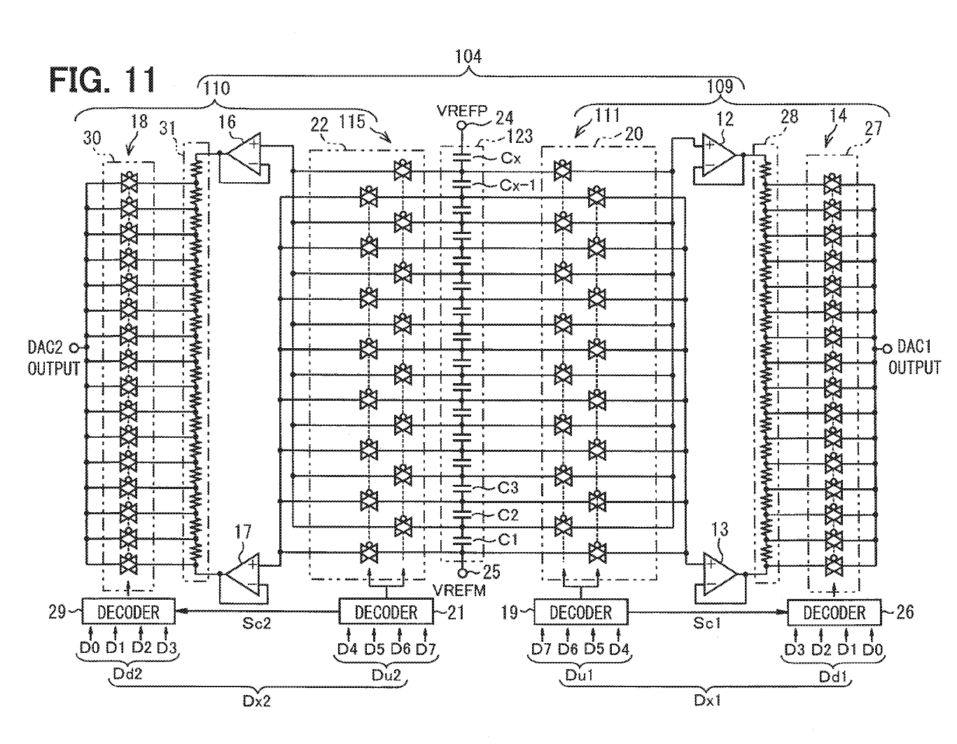

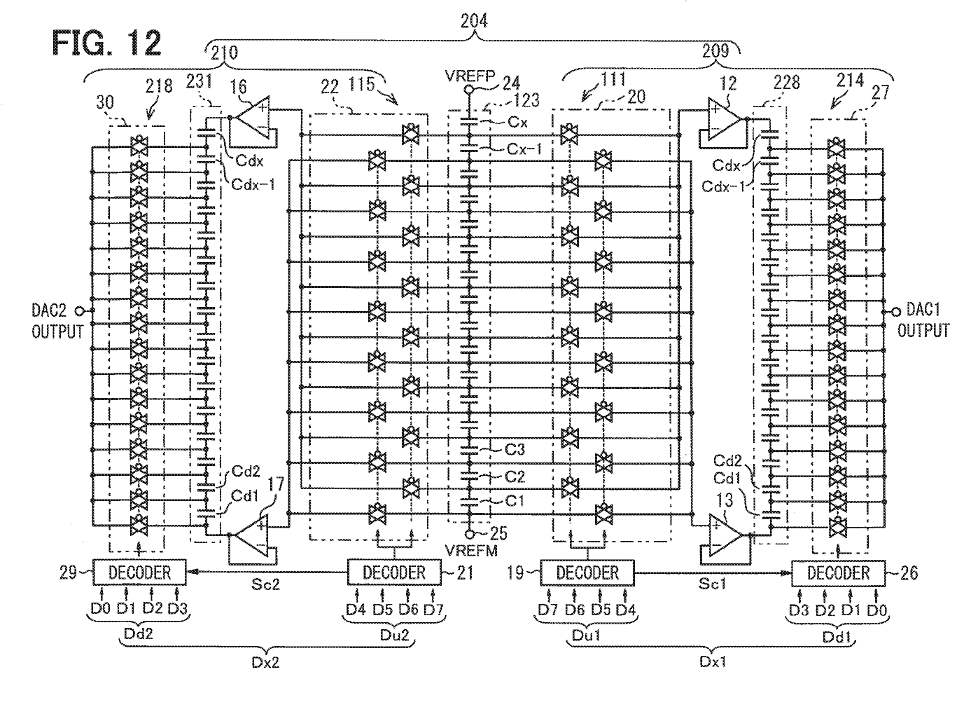

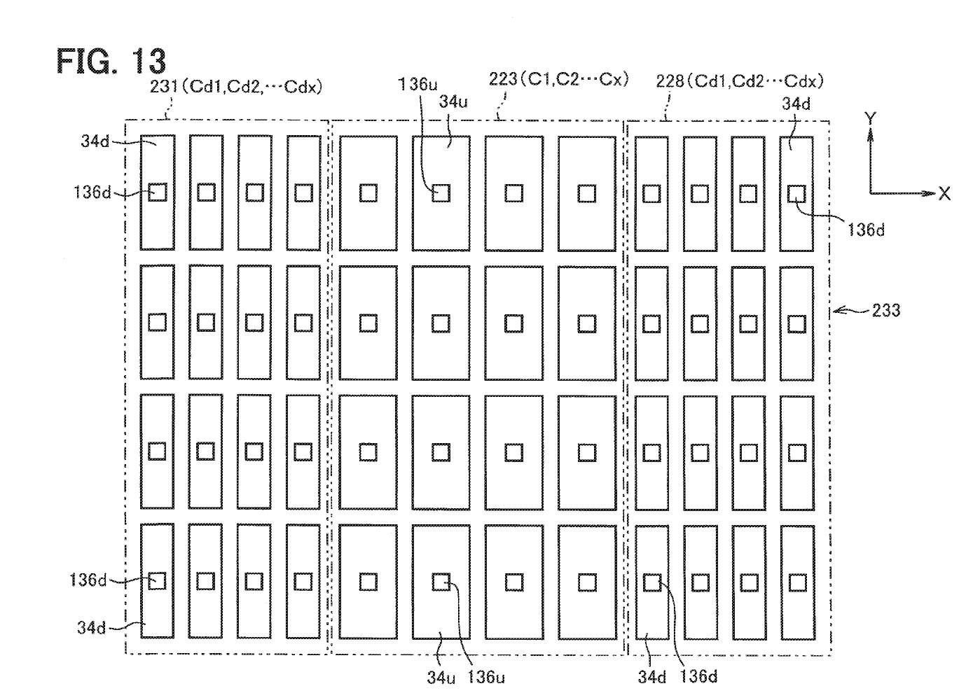

FIG. 11, FIG. 12 and FIG. 13 show a second embodiment. As shown in FIG. 11, an element string circuit 123 is configured as a voltage-dividing capacitor circuit, which is formed of voltage-dividing capacitors C1 to Cx. As shown in FIG. 12, element string circuits 228 and 231 are also configured as voltage-dividing capacitor circuits, each of which is formed of voltage-dividing capacitors Cd1 to Cdx.

In this example, as shown in FIG. 13, the voltage-dividing capacitors C1 to Cx are formed in a semiconductor device 233. As shown in FIG. 13, wiring layers 34u and 34d are arranged on lattice points of respective areas in the same manner as the first embodiment. The widths in the directions X and Y are the same as in the first embodiment. Further, the wiring layers 34u and 34d are arranged to face each other via insulating layers in a direction perpendicular to the directions X and Y and thereby form the voltage-dividing capacitors C1 to Cx. The wiring layers 34u and 34d have contacts 136u and 136d, respectively.

As shown in FIG. 13, facing areas of the voltage-dividing capacitors C1 to Cx of the element string circuit 123, which is at the more-significant side, are preferably made larger than those of the voltage-dividing capacitors Cd1 to Cdx of the element string circuits 228 and 231, which are at the less-significant side. With this configuration, similarly to the first embodiment, the accuracy of capacitance values of the voltage-dividing capacitors C1 to Cx of the more-significant side element string circuit 123 relative to manufacturing error is increased. It is thus possible to minimize the conversion error caused by the more-significant digital data Du1 and Du2. The second embodiment described above thus provides the similar operation and advantage of the first embodiment. Each of the element string circuits 23, 28 and 31, which are at the more-significant side or less-significant side, may be formed as a voltage-dividing circuit using voltage-dividing coils.

### Third Embodiment

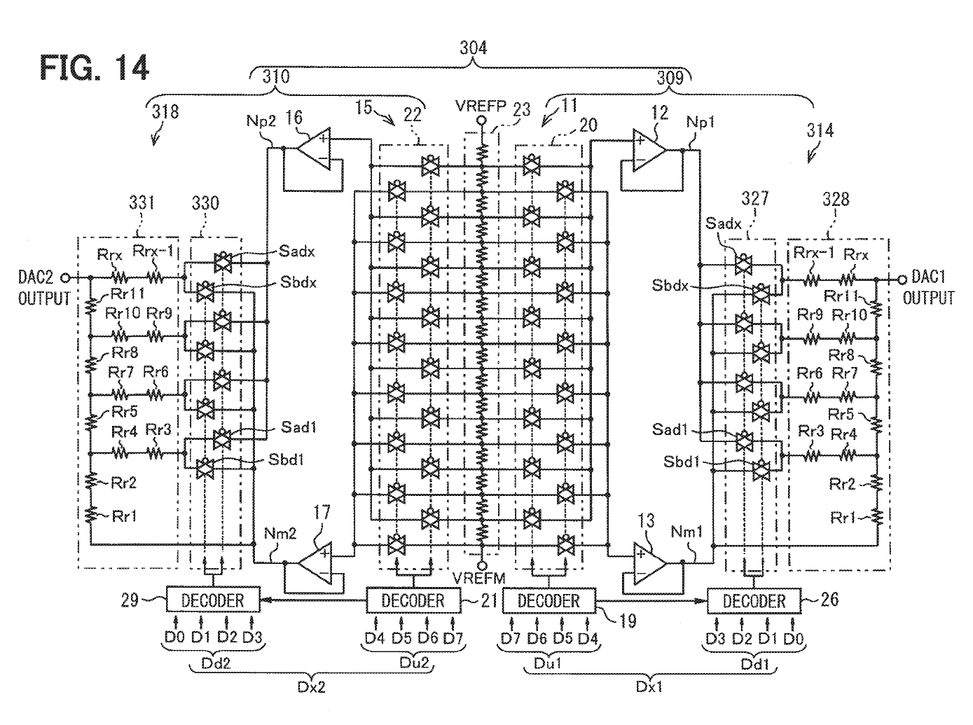

FIG. 14 shows a third embodiment. As shown in FIG. 14, a less-significant D/A conversion part 314 includes the less-significant decoder 26, a less-significant switch-over circuit 327 and an element string circuit 328.

As shown in FIG. 14, the less-significant element string circuit 328 is formed in a R-2R ladder, which includes resistors Rr1 to Rrx. The less-significant switch-over circuit 327 is configured as shown in the figure in correspondence to states of connections of the resistors Rr1 to Rrx. The less-significant switch-over circuit 327 is formed of switches Sad1 to Sadx and Sbd1 to Sbdx.

The node Np1 is connected to one ends of the switches Sad1 to Sadx. The node Nm1 is connected to one ends of the switches Sbd1 to Sbdx. The other ends of the switches Sad1 to Sadx and the other ends of the switches Sbd1 to Sbdx are connected in common. The common connection points of the switches Sad1 to Sadx and Sbd1 to Sbdx and the resistors Rr3, Rr6, Rr9 and Rrx−1 are connected. The resistors Rr1, Rr2, Rr5, Rr8 and Rr11 are connected in series between the node Nm1 and the terminal of the analog signal output DAC1. The resistors Rr3 and Rr4 are connected in series between a common connection point of the switches Sad1 and Sbd1 and a common connection point of the resistors Rr2 and Rr5. The resistors Rrx−1 and Rrx are connected in series between a common connection point of the switches Sadx and Sbdx and a common connection point of the resistors Rrx and Rr11. The other resistors are connected as shown in FIG. 14, although states of connections are not detailed.

The less-significant D/A conversion part 318 includes the less-significant decoder 29, a less-significant switch-over circuit 330 and an element string circuit 331. The less-significant switch-over circuit 330 and the element string circuit 331 of the less-significant D/A conversion part 318 have the same configuration as the less-significant switch-over circuit 327 and the element string circuit 328 of the less-significant D/A conversion part 314. For this reason, the less-significant D/A conversion part 318 is shown with the same reference signs as the resistors Rr1 to Rrx as well as the switches Sad1 to Sadx and Sbd1 to Sbdx, thereby simplifying the detailed description.

For easy understanding, all the resistors Rr1 to Rrx forming the element string circuit 328 are illustrated as having the same resistance values. Since the D/A conversion circuit of R-2R ladder is conventional, detailed description about its operation will not be made. The third embodiment also provides the same operation and advantages as the foregoing embodiments.

### Fourth Embodiment

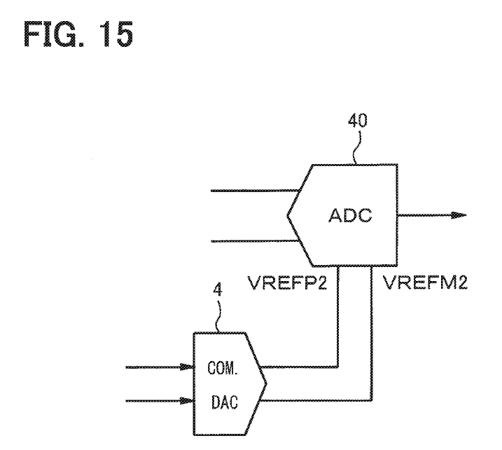

FIG. 15 shows a fourth embodiment. As shown in FIG. 15, the outputs of the common D/A converter 4 described in the first embodiment are applied as the reference voltages VREFP2 and VREFM2 to a differential input type A/D conversion circuit (ADC) 40, which is provided separately. That is, the differential input type A/D conversion circuit 40 is a signal application target. With such a configuration, it is possible to apply the reference voltages VREFP2 and VREFM2 of high accuracy to the A/D conversion circuit 40 and further easily vary the reference voltages VREFP2 and VREFM2.

### Other Embodiment

The electronic control unit is not limited to the embodiments described above and may be implemented with various modifications as exemplified below.

The electronic control unit is exemplified as the signal processing unit 1 for the air-fuel ratio sensor 2. It may however be exemplified as a device, which uses the common D/A converters 4, 104, 204 and 304 or as a single device.

The first and second input digital data Dx1 and Dx2 are split into the more-significant digital data Du1 and Du2 of n1 bits and less-significant digital data Dd1 and Dd2 of n2 bits. However, as far as the element string circuits 23 and 123 are shared by the pair of more-significant D/A conversion parts 11 and 15 or the more-significant D/A conversion parts 111 and 115, the D/A conversion processing may be performed stage by stage by further splitting the less-significant digital data Dd1 and Dd2 into two or more stages. That is, the D/A conversion may be performed by splitting the digital data in a total of three or more stages.

The plural embodiments described above may be combined. For example, the third embodiment may be combined to the first embodiment.

What is claimed is:

1. An electronic control unit for outputting a pair of analog signals to a signal application target as a differential voltage in correspondence to a pair of input digital data, the electronic control unit comprising:
a pair of D/A conversion circuits for performing D/A conversion processing of converting the pair of input digital data to the pair of analog signals, each of the D/A conversion circuits performing conversion processing thereof separately by splitting the input digital data into a more-significant digital data and at least one less-significant digital data, the D/A conversion circuit including a more-significant D/A conversion part and a less-significant D/A conversion part, wherein:
the more-significant D/A conversion part includes a more-significant element string circuit, which outputs a divided voltage by dividing a predetermined reference voltage and outputs a maximum value and a minimum value of an absolute voltage, which are different each other in correspondence to the more-significant digital data, by performing analog conversion processing in correspondence to the more-significant digital data;
the less-significant D/A conversion part performs analog conversion processing by using, as reference voltages, the maximum value and the minimum value of the absolute voltage outputted from the more-significant D/A conversion part;
the more-significant element string circuit is shared by the more-significant D/A conversion parts of the pair of D/A conversion circuits.

2. The electronic control unit according to claim 1, wherein:
the more-significant element string circuit includes one of a voltage-dividing resistor circuit, which includes voltage-dividing resistors for dividing the reference voltage, and a voltage-dividing capacitor circuit, which includes voltage-dividing capacitors for dividing the reference voltage.

3. The electronic control unit according to claim 1, wherein:
the less-significant D/A conversion part includes a resistor string circuit, which is a less-significant element string circuit, which includes plural resistors.

4. The electronic control unit according to claim 1, wherein:
the less-significant D/A conversion part includes a less-significant element string circuit, which is a R-2R ladder circuit formed of plural resistors.

5. The electronic control unit according to claim 1, wherein:
the more-significant D/A conversion part includes a more-significant switch-over circuit, which selects a pair of voltages among the divided voltages of the more-significant element string circuit in correspondence to the more-significant digital data and outputs the absolute voltage in the range having the maximum value and the minimum value corresponding to the selected pair of voltages;
a first buffer circuit for receiving one voltage of the maximum value or the minimum value of the absolute voltage outputted from the more-significant switch-over circuit and applying a received voltage as one reference voltage of the less-significant D/A conversion part; and
a second buffer circuit for receiving the other voltage of the maximum value or the minimum value of the absolute voltage outputted from the more-significant switch-over circuit and applying a received voltage as an other reference voltage of the less-significant D/A conversion part,
wherein, when the more-significant digital data is incremented, the more-significant switch-over circuit maintains the one voltage selected previously to be applied to the first buffer circuit as the one reference voltage and switches over the other voltage selected previously to be applied to the second buffer circuit as the other reference voltage, or the more-significant switch-over circuit maintains the other voltage selected previously to be applied to the second buffer circuit as the other reference voltage and switches over the one voltage selected previously to be applied to the first buffer circuit as the one reference voltage.

6. The electronic control unit according to claim 1, wherein:
the more-significant D/A conversion part has a D/A conversion accuracy higher than that of the less-significant D/A conversion part.

7. The electronic control unit according to claim 6, wherein:
the more-significant element string circuit of the more-significant D/A conversion part is formed of a semiconductor device using a voltage-dividing resistor circuit of voltage-dividing resistors;
the less-significant D/A conversion part further includes in the semiconductor device a less-significant element string circuit, which is a voltage-dividing resistor circuit; and
the more-significant element string circuit of the more-significant D/A conversion part has a cross-sectional area of the voltage-dividing resistor, through which a current flows, larger than that of the less-significant element string circuit of the less-significant D/A conversion part.

8. The electronic control unit according to claim 6, wherein:
the more-significant element string circuit of the more-significant D/A conversion part is formed of a semiconductor device using voltage-dividing capacitors;
the less-significant D/A conversion part further includes in the semiconductor device a less-significant element string circuit of voltage-dividing capacitors; and
the more-significant element string circuit of the more-significant D/A conversion part has a facing area of the voltage-dividing capacitors, through which a current flows, larger than that of the less-significant element string circuit of the less-significant D/A conversion part.

9. The electronic control unit according to claim 1, wherein:
the signal application target is an air-fuel ratio sensor for detecting an air-fuel ratio of air-fuel mixture; and
the less-significant D/A conversion part applies the differential voltage to sensor terminals of the air-fuel ratio sensor.

10. The electronic control unit according to claim 1, wherein:
the signal application target is an A/D conversion circuit, which is a differential input type and provided separately; and
the less-significant D/A conversion part applies the differential voltage as reference voltages of the A/D conversion circuit of the differential input type.
